(19) United States
(12) Patent Application Publication
(10) Pub. No.: US 2022/0043205 A1
(43) Pub. Date: Feb. 10, 2022

(54) AN ULTRA-THIN INTEGRATED AND MANUFACTURE OF THE SAME

(71) Applicant: ADVANCED MICRO FOUNDRY PTE. LTD., Singapore (SG)

(72) Inventors: Xianshu LUO, Singapore (SG); Guo-Qiang LO, Singapore (SG)

(21) Appl. No.: 17/415,024

(22) PCT Filed: Dec. 26, 2019
(86) PCT No.: PCT/SG2019/050641

§ 371 Date: Jun. 17, 2021

(30) Foreign Application Priority Data
Jan. 11, 2019 (SG) 10201900239Y

(51) Int. Cl. G02B 6/122; G02B 6/136

(52) U.S. Cl. CPC G02B 6/1225; G02B 6/136

(57) ABSTRACT

A method of fabricating a semiconductor device, the method comprising: forming a substrate; forming a support layer from a first type of material which is not susceptible to an etch process having a predetermined thickness that is related to a required thickness of the semiconductor device; forming a device on the support layer; forming at least one layer of cladding material on the device; forming a plurality of trenches in the layers that extend at least down to the substrate; applying a film over the cladding material; removing the substrate at least in part using an etching process to separate the device from others on a wafer.

### FIELD OF THE INVENTION

The present invention relates to an ultra-thin integrated chip and manufacture of the same, particularly, but not exclusively to an ultra-thin integrated photonic chip.

### BACKGROUND

In all areas or integrated circuits, chips or semiconductor devices are getting smaller and smaller. As the size reduces, there are more problems associated with achieving a reliable method of manufacturing thin and ultra-thin chips. This is a particular problem for so-called photonic chips that use light instead of electricity. Photonic chips have many uses and are considered particularly useful for molecular environments where they are used as probes and the like.

At present standard photonic chips have a thickness of about 750 μm. These are generally reliably manufactured using current techniques as are discussed in greater detail below. Recent needs are seeking photonic chips that are <50 μm in thickness. The current techniques do not give a reliable yield and often a whole wafer may be destroyed by the necessary techniques of the present methods.

A number of proposals exist. Currently, wafer back-grind after photonic device fabrication is the preferred way for manufacture. However, the back-grind process can only be reliable when the targeted thickness is >100 μm.

It is extremely difficult to control the back-grind thickness for a targeted thickness of <50 μm, as it is simply too thin for existing methods, especially for processed photonics wafers which have a wafer topology and thickness non-uniformities. It is also very difficult to pick up or remove such thin chips from the wafer, which may introduce micro-cracks and chip breakage during delamination processes. As a result, it is likely that most of the devices could be destroyed during wafer back-grind, and/or chip pick up or collection for ultra-thin devices.

FIGS. 1A and 1B show an example of a typical process for manufacturing a photonics chip. A substrate 100 is process at add for example a Buried Oxide Layer (BOX) layer 102 over the substrate. A waveguide 104 is deposited and a cladding layer 106 is applied. The device is processed to include a plurality of deep trenches 108 (of which two are shown). These are to enable the individual chips to be separated from one another at a later stage. Once the processing of the chip has been completed, a backgrind process is carried out on the wafer (mounted on an adhesive backing sheet not shown) resulting in the device as showing in FIG. 1B. If the thickness requirement is not too thin, the final wafer will have a uniform spread of viable devices. However, for thinner devices and for other problems associated with back grinding a whole wafer can be so damaged that there are virtually no chips remaining after the back grind. The wafer will be directly thinned down through mechanical back-grind. The thickness control and the yield will be very low for thin chips.

Other solutions have been proposed to address the needs for ever thinner devices. These include dicing by thinning. This involves a temporary bond of the device wafer into a handle wafer. Thereafter a wafer back grind is carried out followed by an automatic die singulation process. For thin wafer and chips, the same issues remain that the back grind and separation of the chips is fraught with difficulty and yield is low or non-existent. The required thickness for ultra-thin devices is not attainable.

A further proposal is the use of thinning with buried cavities. This entails defining a local buried cavity. Wafer processing is followed by trench etching and a chip singulation through pick-and-place. This type of process is not viable for thin devices due to poor yields and reliability. In addition, the need to pre-define the cavity locally will give rise to additional process costs.

A further method is a known epitaxial growth and selective etching technique. A Silicon (Si) epitaxial layer with a highly doped film is deposited on a wafer, then a Si epitaxial layer with a lightly doped film is deposited. The wafer undergoes a back grind to thin it down and then a Si etch to thin down further. Again the use of epitaxial layers and back grinding do not work well for photonic applications and the rate of failure is too high for the process to be suitable for chips of the order of >100 μm in thickness. This method has a high cost epitaxy process and a long process time and is simply not applicable for photonic usage due to the possible high loss induced by the doped film.

An object of the present invention is to provide a simple manufacture method in order to produce thin integrated photonic chips with easy removal along with more controllable thickness outcome.

Another object of the present invention is to implement an ultra-thin photonics chip and a method of manufacture which overcomes at least some of the problems associated with the prior art.

The embodiments described below are not limited to implementations which solve any or all of the disadvantages of the prior art.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to an aspect of the present invention there is provided a semiconductor device comprising a support layer which is formed from a material that is not susceptible to an etching process and which support layer can be deposed in manufacture to a predetermined thickness to thereby precisely control a required thickness of the device.

Preferably, the support layer comprises a buffer layer.

Preferably, the buffer layer comprises SiO2, SiON, SiN.

Preferably, the support layer further comprising an additional etch stop layer.

Preferably, the support layer is the order of few 10s μm.

Preferably, the device is a photonic chip.

Preferably, the device is an ultra-thin device.

According to an aspect of the present invention there is provided a method, the method comprising: forming a substrate; forming a support layer from a first type of material which is not susceptible to an etch process having a predetermined thickness that is related to a required thickness of the semiconductor device; forming a device on the support layer; forming at least one layer of cladding material on the device; forming a plurality of trenches in the layers that extend at least down to the substrate; applying a film over the cladding material; removing the substrate at least in part using an etching process to separate the device from others on a wafer.

Preferably, further comprising removing the substrate using a combination of a backgrind and wet etch process.

Preferably, further comprising forming an additional etch stop layer over the support layer.

Preferably, the support layer comprises a buffer layer and comprises at least one of SiO2, SiON and SiN

Preferably, further comprising separating the chip by removing the film such that edges of individual device is defined by the trenches.

Preferably, further comprising forming the trenches around each side of the device.

Preferably, further comprising controlling the forming of the support layer to produce a device having the required thickness.

Preferably, the film is a non-etchable material.

The preferred features may be combined as appropriate, as would be apparent to a skilled person, and may be combined with any of the aspects of the invention.

### BRIEF DESCRIPTION OF THE DRAWINGS

Embodiments of the invention will be described, by way of example, with reference to the following drawings, in which:

FIG. 1 shows a schematic diagram of a first prior art method;

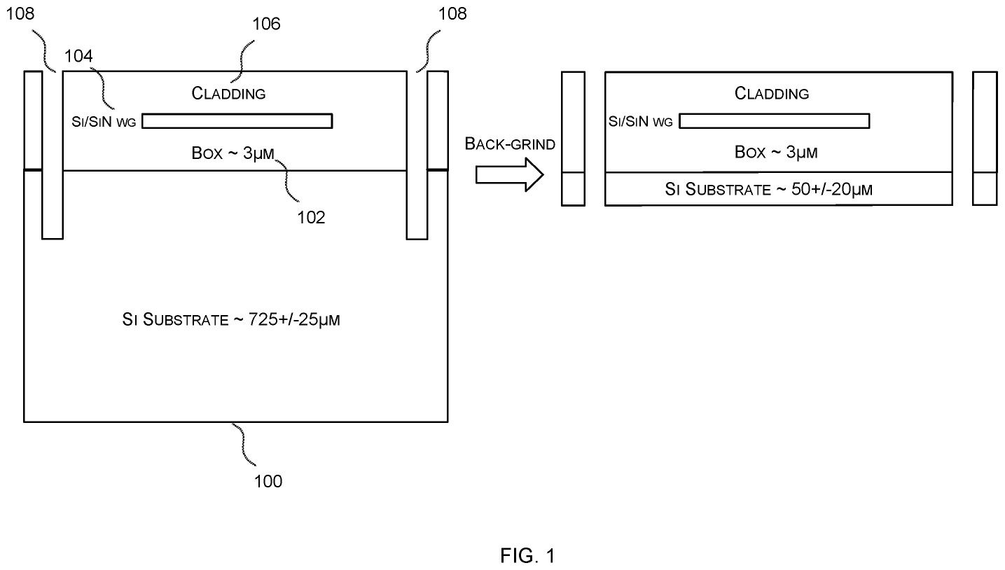

FIG. 2 is a schematic diagram showing a process for manufacturing ultra-thin photonics chips according to an embodiment of the present invention.

Common reference numerals are used throughout the figures to indicate similar features.

### DETAILED DESCRIPTION

Embodiments of the present invention are described below by way of example only. These examples represent the best ways of putting the invention into practice that are currently known to the Applicant although they are not the only ways in which this could be achieved. The description sets forth the functions of the example and the sequence of steps for constructing and operating the example. However, the same or equivalent functions and sequences may be accomplished by different examples.

The present invention relates to a simple manufacturing method to produce a thin integrated chip or semiconductor device, such as a photonics chip which can be easily singulated and in which an improved yield and controllable thickness are achieved.

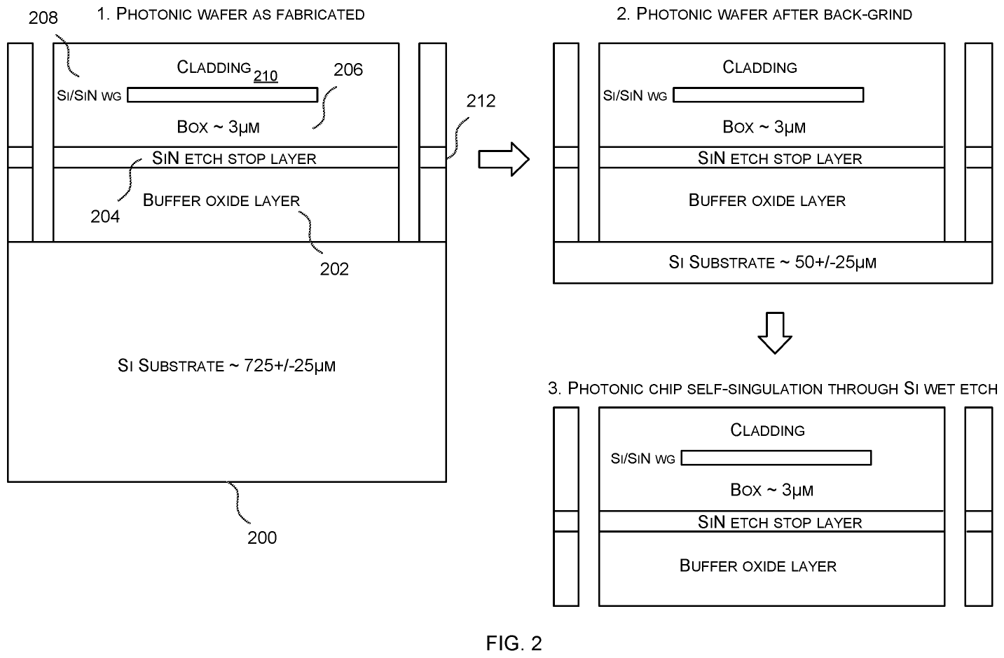

FIG. 2 shows an example method of manufacturing a photonics chip having a thickness of anything from a few μm to a few 10s μm.

A silicon substrate 200 is taken. This can be any appropriate size for example of the order of 725 μm (±25 μm). In accordance with the present invention the material of the substrate needs to be etchable so that it can be removed in a later stage of the process. This will be described in more detail below. A preferred material is silicon, but other substrates may be used instead, as long as the material can be removed as required below. For most applications a silicon substrate is used. However, a glass wafer is also usable, in which case the layers and the process flow will be adapted to suit the relevant materials.

A buffer layer 202 is deposited on to the substrate. The thickness of this buffer layer controls the thickness of the eventual chip. The thickness of the chip is thus controlled precisely, as the thickness of this deposition can be carefully controlled and be of a predetermined thickness depending on requirements. The buffer layer can be of any appropriate material which can serve as etching stop layer during the etching of the substrate, including for example SiO₂, SiON, SiN, etc. The buffer oxide layer is selected to be a material which is not etchable or with a high etching selectivity by the later wet etching process.

Once the overall device thickness is decided, the fabricator knows the normal thickness of all necessary device layers and then can calculate the required thickness of the buffer layer to arrive at the required overall device thickness.

As indicated above the thickness of the buffer layer defines the thickness of the final chip. Different types of chip may be made to be different thicknesses or the same type of chip may be required to be different predetermined thicknesses for one application or another. By way of example the buffer layer may be, for such as Neuro photonics application, ˜20-30 μm.

In a next step of the process another etch stop layer 204 is deposited over the buffer layer using a Chemical Vapor deposition (CVD) process. This layer has a thickness of about few μm to few 10s μm and comprises for example, could be SiN, SiON and is generally used to separate the BOX and buffer layer, depending on the necessity. The etch stop layer is used to stop etching in a subsequent step of the process as will be described in greater detail below. There are essentially two different purposes for this layer. The first is to separate the BOX and buffer layers. The second is to serve as etch stop layer for oxide cladding etch before etching buffer layer in the case that buffer layer is oxide. The etch stop layer could be omit based on the application and also the design requirements and materials used.

In a next step of the process a BOX layer 206 is deposited over the etch stop layer. This layer has a thickness of a few μm and comprises for example an oxide. This is the photonic function layer that has low refractive index comparing to the waveguide layer in order for optical light confinement.

In a next step of the process, a waveguide 208 is deposited over the BOX layer. This layer has a thickness of between a few tens of nm to a few μm and comprises for example silicon, silicon nitride (SiN); silicon oxynitride (SiON), Polycrystalline Si or amorphous Si. In a photonics chip, for example a waveguide is deposited above the BOX layer. Different devices may be fabricated at this point as is required for the proposed chip. For different types of chip, other devices may be fabricated. Any appropriate device could be added depending on the application and function of the chip.

In a next step of the process, an upper cladding layer 210 is deposited over the device depending on the necessity. This layer has a thickness of a few μm and comprises for example and oxide layer.

In a next process step, deep trenches 212 are applied over the wafer. Two are located on either side of the waveguide in the example shown. The trenches are formed by any appropriate process and may include for example Reactive Ion Etching (RIE) or Inductively Coupled Plasma Etching (ICP). The trenches are formed to be only as deep as the substrate and there is substantially no trench in the substrate. The reason for this will be explained in greater detail below. Although not shown there are trenches in both the X and Y directions over the wafer separating each chip from the next.

After the wafer has been fabricated and the trenches formed, the wafer is attached to a film, such as a Mylar film (not shown) or UV tape. The film is applied to the cladding layer to hold the chips in place during the next stages of the process. Once supported by the film, the wafer undergoes a process to remove the entire substrate. This could include at least in part a backgrinding process. Using the backgrind, the substrate is reduced to about 50 μm (±25 μm) from its original thickness, to ensure the total remaining thickness to be about 100 μm, which is a minimum thickness to ensure the backgrind yield is adequate. The amount of substrate removed by the back grinding is selected to be the optimal for preventing damage to the overlying surfaces of the wafer. The resultant device is shown in FIG. 6. The backgrind process comprises grinding away a portion of the substrate whilst supporting the wafer on the film using a grinder.

The material of the film is ideally not etchable so that the wafer stays in tact during the following wet etch.

In a next stage of the invention the ground wafer undergoes a silicon wet etch process, which removes the remainder to the substrate as shown in FIG. 6. The wet etch process comprising exposing the substrate silicon to a solution such as Tetramethylammonium hydroxide (TMAH) in order to remove the remaining silicon and automatically separate the chips.

As can be seen in FIG. 6 the wet etch process removes all material up to the bottom of the deep trenches. The buffer layer is not etched as it is made from non-etchable material. The thickness of the buffer layer is predefined so that the resultant chip is of the required thickness. The resultant device thus has the buffer layer as a support layer, rather than substrate which would normally serve this purpose.

It should be noted that the removal of the substrate leaving the buffer layer later as the support layer for the device can be carried out in one or more different steps. For example, backgrinding and wet etching; in some cases just wet etching; or any other appropriate step or combination of steps.

As a result of the trenches, the individual devices can be easily separated from one another over the area of the wafer. Apart from the film support there is nothing holding the individual chips together once the substrate has been etched away. The individual chips are either held in place by the film (not shown) or if the film is etched can be recuperated post etching.

The method and final resultant chip of the present invention is a photonics chip. However, it will be appreciated that the process could be used for other type of ultra-thin processing method and chips. Including for example the thin devices such as a flexible display.

The present invention may include a number of variations and alternatives to the examples described above. These are intended to be encompassed within the scope of the invention. The invention is specifically for photonic chips but may also be used on other types of device, for example flexible electronic devices.

According to an aspect of the present invention there is provided a semiconductor device comprising a support layer which is formed from a material that is not susceptible to an etching process and which support layer can be deposed in manufacture to a predetermined thickness to thereby precisely control a required thickness of the device.

Preferably, the support layer comprises a buffer layer.

Preferably, the buffer layer comprises SiO2, SiON, SiN.

Preferably, the support layer further comprising an additional etch stop layer.

Preferably, the support layer is the order of 10s of μm.

Preferably, the device is a photonic chip.

Preferably, the device is an ultra-thin device.

According to an aspect of the present invention there is provided a method, the method comprising: forming a substrate; forming a support layer from a first type of material which is not susceptible to an etch process having a predetermined thickness that is related to a required thickness of the semiconductor device; forming a device on the support layer; forming at least one layer of cladding material on the device; forming a plurality of trenches in the layers that extend at least down to the substrate; applying a film over the cladding material; removing the substrate at least in part using an etching process to separate the device from others on a wafer.

Preferably, further comprising removing the substrate using a combination of a backgrind and wet etch process.

Preferably, further comprising forming an additional etch stop layer over the support layer.

Preferably, the support layer comprises a buffer layer and comprises at least one of SiO₂, SiON and SiN.

Preferably, further comprising separating the chip by removing the film such that edges of individual device is defined by the trenches.

Preferably, further comprising forming the trenches around each side of the device.

Preferably, further comprising controlling the forming of the support layer to produce a device having the required thickness.

Preferably, the film is a non-etchable material.

Any range or device value given herein may be extended or altered without losing the effect sought, as will be apparent to the skilled person. Similarly any material can be replaced by another having similar properties.

It will be understood that the benefits and advantages described above may relate to one embodiment or may relate to several embodiments. The embodiments are not limited to those that solve any or all of the stated problems or those that have any or all of the stated benefits and advantages.

Any reference to ‘an’ item refers to one or more of those items. The term ‘comprising’ is used herein to mean including the method blocks or elements identified, but that such blocks or elements do not comprise an exclusive list and a method or apparatus may contain additional blocks or elements.

The steps of the methods described herein may be carried out in any suitable order, or simultaneously where appropriate. Additionally, individual blocks may be deleted from any of the methods without departing from the spirit and scope of the subject matter described herein. Aspects of any of the examples described above may be combined with aspects of any of the other examples described to form further examples without losing the effect sought.

It will be understood that the above description of a preferred embodiment is given by way of example only and that various modifications may be made by those skilled in the art. Although various embodiments have been described above with a certain degree of particularity, or with reference to one or more individual embodiments, those skilled in the art could make numerous alterations to the disclosed embodiments without departing from the spirit or scope of this invention.

1. A semiconductor device comprising a buffer layer and an etch stop layer, wherein the buffer layer comprises at least one of SiO₂, SiON and SiN and is of predetermined thickness, wherein the etch stop layer has been deposited over the buffer layer, wherein the device is less than 50 μm in thickness.

2. The semiconductor device according to claim 1, wherein the buffer layer has a thickness of 3 to 30 μm.

3. The semiconductor device according to claim 1, wherein the device is a photonic chip.

4. A method of fabricating a plurality of semiconductor devices, the method comprising:
forming a substrate;
forming a buffer layer over the substrate from at least one of SiO₂, SiON and SiN having a predetermined thickness that is related to a required thickness of the semiconductor device;
forming an etch stop layer over the buffer layer:
forming a plurality of devices on the etch stop layer;
forming at least one layer of cladding material on the device;
forming a plurality of trenches in the layers that extend at least down to the substrate;
applying a film over the cladding material;
removing the substrate at least in part using an etching process to separate each device from others on a wafer, wherein the device is less than 50 μm in thickness.

5. The method according to claim 4, further comprising removing the substrate using a combination of a backgrind and wet etch process.

6. The method according to claim 4, further comprising separating the device by removing the film such that edges of individual device is defined by the trenches.

7. The method according to claim 4, further comprising forming the trenches around each side of the device.

8. The method according to claim 4, further comprising controlling the forming of the buffer oxide layer to produce a device having the required thickness.
